(19) United States
(12) Patent Application Publication
(10) Pub. No.: US 2009/0071525 A1
(43) Pub. Date: Mar. 19, 2009

(54) Cooling Hot-Spots by Lateral Active Heat Transport

(75) Inventors: Marc Scott Hodes, Dublin (IE); Shankar Krishnan, Dublin (IE)

Correspondence Address: HITT GAINES, PC;ALCATEL-LUCENT, PO BOX 832570, RICHARDSON, TX, 75083, US

(73) Assignee: Lucent Technologies, Inc., Murray Hill, NJ (US)

(21) Appl. No.: 11/856,201

(22) Filed: Sep. 17, 2007

(51) Int. Cl. H01L 35/32; H01L 21/50

(52) U.S. Cl. 136/204; 438/122; 62/3.3; 62/3.7; 257/E23.082; 257/E21.499

(57) ABSTRACT

An apparatus includes a thermoelectric cooler adjacent to a surface of a device substrate and including a first set of one or more metal electrodes, a second set of one or more metal electrodes, and one or more semiconductor members. Each member includes a material different from the device substrate and physically joins a corresponding one electrode of the first set to a corresponding one electrode of the second set. The electrodes and at least one member are configured to transport heat to or from a thermal load in a direction parallel to the surface of the device substrate.

### TECHNICAL FIELD OF THE INVENTION

The present invention is directed, in general, to thermoelectric coolers.

### BACKGROUND OF THE INVENTION

A thermoelectric cooler (TEC), also known as a Peltier cooler, is a solid-state electrical device that may be configured to transport heat when current is passed through a number of semiconducting “pellets” to exploit the Peltier effect. The pellets are typically configured in a series circuit arranged to produce a desired degree of cooling and device resistance. The direction of heat transport in a TEC may be determined by the direction of current flow through the pellets. The magnitude of the heat transport is determined in part by the magnitude of the current.

TECs provide a convenient and effective means of temperature control in many applications. In one such application, these devices are used in electronics systems to reduce the operating temperature of electronic components. Such cooling is especially desirable where system design constraints preclude or limit the use of cooling fins or forced air flow, or when cooling is only desired for specific components. TECs may also be used to refrigerate a component by cooling the component below the ambient temperature. Other applications include precise temperature control of photonic devices by providing heating and/or cooling to maintain desired device temperature.

### SUMMARY OF THE INVENTION

In one embodiment, an apparatus includes a thermoelectric cooler adjacent to a surface of a device substrate and including a first set of one or more metal electrodes, a second set of one or more metal electrodes, and one or more semiconductor members. Each member includes a material different from the device substrate and physically joins a corresponding one electrode of the first set to a corresponding one electrode of the second set. The electrodes and at least one member are configured to transport heat to or from a thermal load in a direction parallel to the surface of the device substrate.

Another embodiment is a method that includes forming a thermoelectric cooler adjacent a surface of a device substrate. The cooler includes a first set of one or more metal electrodes, a second set of one or more metal electrodes, and one or more semiconductor members including a material different from the device substrate. Each member physically joins a corresponding one electrode of the first set to a corresponding one electrode of the second set. The electrodes and at least one member are configured to transport heat to or from a thermal load on the device substrate in a direction parallel to the adjacent surface of the device substrate.

Another embodiment is a method including increasing a heat transfer area associated with an electronic device on a device substrate by operating a thermoelectric cooler adjacent the electronic device. The thermoelectric cooler includes a first set of one or more metal electrodes, a second set of one or more metal electrodes, and one or more semiconductor members. Each member physically joins a corresponding one electrode of the first set to a corresponding one electrode of the second set. The sets of electrodes and the one or more members form an electrical conduction path within the members that is parallel to the device substrate. The one or more semiconductor members is formed of a material different than said device substrate has a cross-sectional area that increases in a direction parallel to the electrical conduction path.

### BRIEF DESCRIPTION OF THE DRAWINGS

Various embodiments are understood from the following detailed description, when read with the accompanying figures. Various features may not be drawn to scale and may be arbitrarily increased or reduced in size for clarity of discussion. Reference is now made to the following descriptions taken in conjunction with the accompanying drawings, in which:

FIGS. 1A-1D illustrate embodiments of a lateral thermoelectric cooler (TEC);

FIG. 2 illustrates a TEC pellet;

FIG. 3 illustrates a lateral TEC embedded in a device substrate;

FIG. 4 illustrates a closed-loop lateral TEC embedded in a device substrate;

FIG. 5 illustrates a cascaded TEC;

FIGS. 6A-6B illustrate various embodiments of placement of a TEC;

FIGS. 7A-7D illustrate temperature profiles associated with a thermal load with circular TECs of various diameters; and

FIG. 8 illustrates an embodiment including active temperature control.

### DETAILED DESCRIPTION

In a conventional thermoelectric cooler (TEC), pellets are typically arranged in a Cartesian geometry. While such a design provides relatively uniform cooling over the surface of the TEC, it may not effectively accommodate an electronic device or a portion of a device that has a power dissipation concentrated in an area significantly less than the effective cooling area of the TEC. An electronic device is referred to generally herein as a thermal load, or simply a “load” for brevity. Such a load may develop a “hot spot,” a localized region having a significantly higher temperature than a background temperature of a substrate on which the load is placed. A hot spot may result in reduced efficiency and lifetime of the load. Moreover, dissipation of heat from a hot spot may be limited by resistance of the thermal path between the hot spot and a thermal sink element such as, e.g., a finned heat sink.

The reliability of many electronic devices is reduced when their temperature of operation increases. In some cases, electromigration in metal interconnects is accelerated by a higher temperature of operation. In other cases, the higher temperature may provide activation energy to promote diffusion of dopants in transistors, or contaminants through protective layers. In some cases, the lifetime of the device may be reduced exponentially as the operating temperature increases. Thus, in general it is desirable to operate an electronic device at a lower temperature than a higher temperature, and in any case, at a temperature at or below a maximum specified by a manufacturer of the device.

The embodiments described herein recognize that a thermoelectric cooler (TEC) may be used to transport heat laterally over a substrate supporting the device (a “device substrate”) to lower the temperature of a hot spot associated with a thermal load. Heat produced by the load may be removed more efficiently by moving heat to cooler areas of the device substrate. The total area available to dissipate the heat may be increased, thus reducing thermal resistance between the load and a radiator or heat sink. In this manner, the peak temperature of the thermal load may be reduced.

A description of some TECs appears in U.S. patent application Ser. No. 11/618,056 to Hodes, et al., incorporated by reference as if reproduced herein in its entirety. Some portions of that description are also summarized herein.

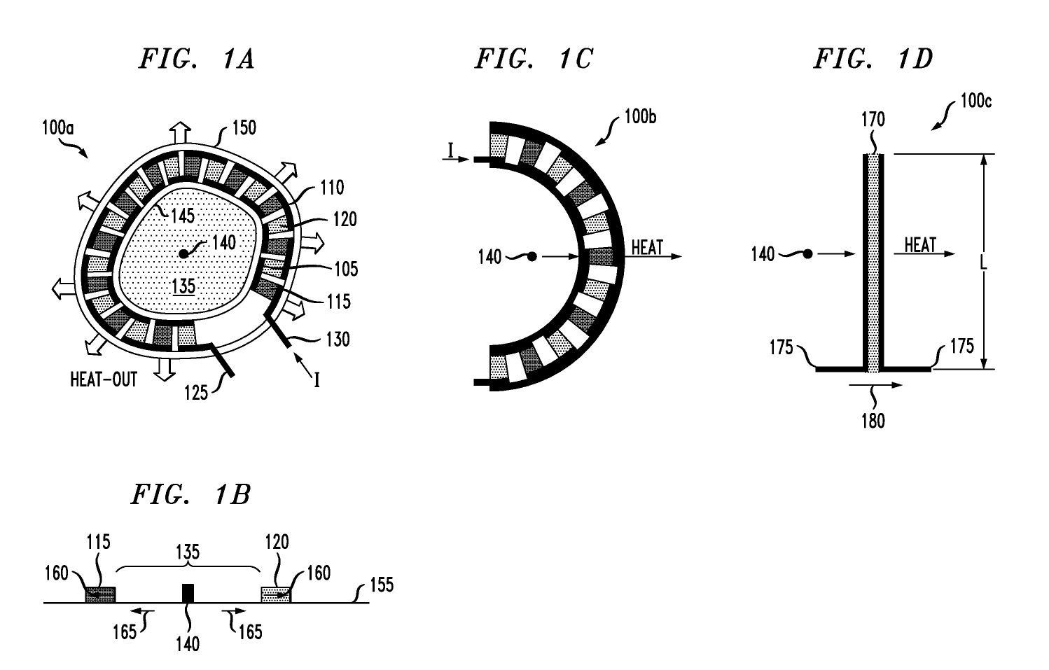

FIG. 1A is a plan view of an embodiment of a TEC 10a designed primarily to transport heat parallel to an adjacent surface of a device substrate. The TEC 10a includes a first set 105 of metal electrodes, a second set 110 of metal electrodes and semiconductor members 115, 120. Each semiconductor member 115, 120 physically joins a corresponding electrode from the first set 105 to a corresponding electrode from the second set 110. In this manner, a serial current path is formed from a terminal 125 to a terminal 130 via the metal electrodes 105, 110 and the semiconductor members 115, 120. The TEC 10a encloses a region 135 that includes a thermal load 140 that may be an electronic device that dissipates power when operating.

The electrodes 105 and the electrodes 110 together form a set of electrodes. The electrodes 105 form a first non-null subset of this set of electrodes. Similarly, the electrodes 110 form a second non-null subset of this set of electrodes. The first non-null subset and the second non-null subset are disjoint, meaning no electrode belongs to both sets.

The doped semiconductor members 115, 120 are commonly referred to in the art as pellets, and are referred to as such hereinafter. The pellets 115, 120 may be complementary-doped, meaning that a subset 115 is n-doped, and a subset 120 is p-doped, e.g. The pellets 115, 120 may be a semiconducting material chosen for efficient operation of the TEC 10a at an anticipated operating temperature. Example materials include, e.g., Bi₂Te₃, Zn₄Sb₃, PbTe, and CeFe₄Sb₁₂, and superlattices of Bi₂Te₃/Sb₂Te₃. In some cases, silicon may be used as an effective pellet material.

The choice of material for the pellets 115, 120 is guided in part by the intended operating temperature of the TEC 100a. Bi₂Te₃ is widely used, and is well suited for use at an operating temperature ranging from about 0° C. to about 200° C. It is therefore assumed for the present discussion that Bi₂Te₃ is used for the pellets 115, 120, while recognizing that other doped semiconducting materials may be used.

The n-type pellets 115 are typically provided with n-type semiconducting properties by either doping with impurity atoms or varying the stoichiometry of the pellet material from ideal ratios of constituent elements. For example, a fraction of tellurium atoms may be substituted with selenium to produce n-type Bi₂Te₃. In a similar manner, p-type characteristics are conventionally imparted to the p-type pellets 120.

The electrodes 105, 110 may be formed of a metal with sufficient conductivity so that insignificant ohmic heating is produced in the electrodes 105, 110 by a current I used to operate the TEC 10a. In addition, a conductive diffusion barrier (not shown) may be formed between the electrodes 105, 110 and the pellets 115, 120 to reduce diffusion of the electrode material into the pellets 115, 120. The barrier may also promote formation of a low-resistance interface with the pellets 115, 120. A low-resistance interface may be desirable to reduce power dissipation at the electrode/pellet interface because dissipated power results in additional heat, generally reducing the efficiency of the TEC 100a. High resistance may occur, e.g., from imperfections at the interface when the electrodes 105, 110 are soldered or otherwise joined to the pellets 115, 120. The diffusion barrier may also be chosen to be metallurgically compatible with the electrode material. The barrier is compatible when it forms a mechanically strong bond with the electrodes, and interdiffusion of the electrode and barrier is low enough that any electrode material diffusing into the pellets does not impair the operation of the TEC over its expected lifetime. As a non-limiting example, when the electrode material is copper, nickel may be used as a diffusion barrier having the desired characteristics.

The TEC 10a may optionally include an inner electrical insulator 145 and an outer electrical insulator 150. The insulators 145, 150 are analogous to insulating substrates on which pellets and electrodes are assembled in Cartesian TECs. Such layers may be desirable, e.g., when additional mechanical strength of the TEC 100a is desired, or to protect the electrodes 105, 110 from contact with other components. In some cases, it may be desirable that the insulators 145, 150 have relatively high thermal conductivity to enhance heat transport from or to the region 135. Suitable insulating materials include alumina, aluminum nitride and beryllium nitride, and polymers loaded with a thermally conducting filler material.

A TEC employs current to transport thermal energy. When the current I flows through the path formed by the electrodes 105, 110 and the pellets 115, 120, thermal energy (heat) is absorbed from the electrodes 105 and transported outward to, and dissipated by, the electrodes 110. It is believed that in the p-type pellets 120, holes transport thermal energy in the direction of the current I, while in the n-type pellets 115, thermal energy is transported counter to the direction of the current. Thus, the pellets 115, 120 can act in parallel to transport thermal energy from the region 135 of the TEC 10a to the perimeter. When used in this manner, the TEC 100a acts to increase the area over which heat produced by the thermal load 140 is distributed. Conversely, if heating of the region 135 is desired in some applications, the direction of the current I may be reversed to cause heat to be transported into the region 135.

FIG. 1B illustrates a sectional view of the TEC 10a on a device substrate 155. The pellets 115, 120 include a material different from the device substrate 155, e.g., a different alloy. For example, the device substrate 155 may be a silicon wafer, and the pellets 115, 120 may be one of the other semiconductor alloys discussed previously that are suited for efficient operation of the TEC 10a. When the TEC 10a is operated in a cooling mode, e.g., transporting heat from the region 135, a thermal gradient is formed across the pellets 115, 120 as indicated by flux vectors 160. When the TEC 100 is thermally coupled to the device substrate 155, heat is transported from the portion of the device substrate 155 in close thermal communication with the cooler end of the pellets 115, 120 as denoted by the flux vectors 165. From the region 135, the flux vectors 165 transport heat in an outward direction substantially parallel to the adjacent surface of the device substrate 155 on which the load 140 is placed. When the TEC 100a forms a closed, or nearly closed geometry, as illustrated in FIG. 1A, the region 135 is cooled by the outward transport of heat along the adjacent surface of the device substrate 155. Thus, when the region 135 includes a load or hot spot, the temperature thereof may be reduced by said heat transport.

The TEC need not enclose a region. FIG. 1C illustrates a plan view of an embodiment in which a TEC 100b is an open form. The thermal load 140 may be cooled thereby as described above. Any arbitrary planar shape of the TEC 100b may be determined from knowledge of the thermal environment of the thermal load 140. When an open-form TEC is curved, as illustrated in FIGS. 1A and 1C, the TEC may be operated to spread heat from a smaller area on one side of the TEC, to a larger area on the other side of the TEC, or vice-versa.

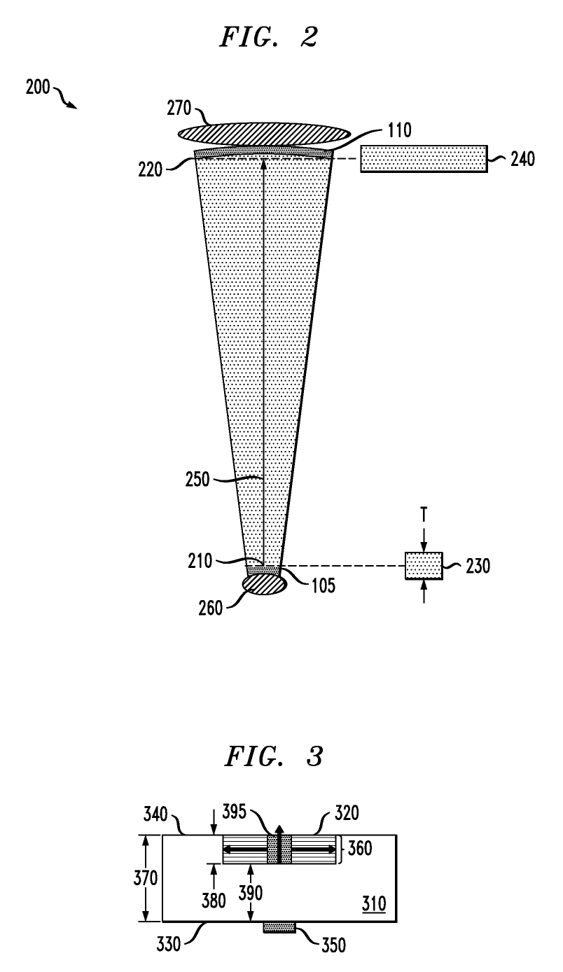

FIG. 2 illustrates a single pellet 200 in greater detail. The geometry of the pellet 200 is a non-limiting example of one or more of the pellets 115, 120. A smaller end 210 of the pellet 200 is in contact with one of the electrodes 105. A larger end 220 is in contact with one of the electrodes 110. The pellet 200 has a thickness T, so the smaller end 210 has an associated cross-sectional area 230, and the larger end 220 has an associated cross-sectional area 240. Electrodes 105, 110 that are connected directly through a single pellet 200 are neighboring electrodes. A vector 250 indicates the direction of heat flow in the pellet 200 when the TEC 100 is operated to transport heat from the electrode 105 to the electrode 110.

The electrode 105 is viewed as being associated with an area 260 of the device substrate 155 to or from which the electrode 105 may transport heat. Similarly, the electrode 110 is associated with an area 270 of the device substrate 155 to or from which the electrode 110 may transport heat. Because the electrodes 105, 110 are about coextensive with the cross-sectional areas 230, 240 of the pellet 200 to which they are attached, the area 270 is larger than the area 260. Thus, when configured to transport heat from the first electrode 105 to the electrode 110, the heat removed from the area 260 is transported to a larger area. In this manner, the area over which the heat removed from the area 260 is dissipated to a heat sink is increased, resulting in greater efficiency of dissipation.

In some cases, it may be desirable to transport heat to the thermal load 140. In a nonlimiting example, a TEC may be used in an active control system to maintain a desired operating temperature of the thermal load 140. In such a case, the control system may move heat away from or towards the thermal load 140 to regulate the temperature. When heat is transported to the thermal load 140, the flux vector 250 is reversed, and heat is transported from the area 270 to the area 260. Thus, in such cases, heat may be transported from a larger area to a smaller area.

Turning to FIG. 1D, illustrated is a plan view of an embodiment in which a TEC 100c has only one pellet 170. The TEC 100c also represents the limit of the open geometry, e.g., a line. Current is provided by electrodes 175 to produce thermal flux 180. This embodiment offers simplicity of implementation, as only one pellet type is needed. However, the resistance of the TEC 100c will generally be inversely related to its length L. Thus, this implementation may not be suitable in applications in which a low resistance is undesirable. In such applications, a complementary-pellet design such as, e.g., the TEC 100a, or TEC 100b may be better suited, though a linear arrangement of the pellets could still be used if desired.

The example TECs 100a, 100b, 100c illustrate a variety of possible configurations of TECs configured for lateral heat transport. In general one or more TECs may be configured in largely arbitrary shapes to accommodate one or more thermal loads 140 on the device substrate 155. Any configuration of one or more TECs configured in any combination of shapes is within the scope of this description.

FIG. 3 illustrates a device substrate 310 in which a TEC 320 is embedded. In the illustrated embodiment, the device substrate 310 has an active side 330 and an inactive side 340. This configuration may be desirable, e.g., in a packaging application in which an integrated circuit die is inverted, such a ball-grid array (BGA) package. Though not illustrated, embodiments in which the die is not inverted are within the scope of the disclosure. Also within the scope of the disclosure are embodiments in which a TEC is mounted on or embedded in the active side of a device substrate.

The active side 330 is the side on which most or all of electronic devices are located, e.g., the device side of a silicon die. The active side 330 has one or more electrical devices that dissipate power when operated. A thermal load 350 causes a hot spot, e.g., a region of locally maximum temperature that may reduce the lifetime of one or more devices within the hot spot.

The inactive side 340 is, e.g., the backside of a silicon die. In the illustrated embodiment, a recess 360 is formed in the inactive side 340 of the device substrate 310, and the TEC 320 is placed therein. The recess 360 may be formed, e.g., by a plasma etch. In some cases, the recess 360 is formed such that the TEC 320 top surface is about flush with the surface of the device substrate 310. This configuration may be advantageous when, e.g., a heat sink is placed over the device substrate 310 and the TEC 320 to aid the dissipation of heat. Also, thermal coupling between the TEC 320 and the device substrate 310 may be maximized when the TEC 320 is completely embedded.

The device substrate 310 has a thickness 370. In a nonlimiting example, this thickness is about 0.5 mm thick, such as, e.g., after thinning a semiconductor wafer prior to packaging die formed therefrom. The TEC 320 has a thickness 380 that is less that the thickness 370. When a flush configuration is desired to maintain mechanical integrity of the device substrate 310, it may be desirable to leave a remaining thickness 390 of about 100 μm or greater after forming the recess 360. However, it may also be desirable to minimize the remaining thickness 390, consistent with maintaining mechanical integrity, to provide low thermal resistance between the thermal load 350 and the TEC 320. Thus, in this example, the thickness of the TEC 320 is preferably about 400 μm.

The TEC 320 may also include a thermally conductive core 395. The core 395 may conduct heat vertically through the TEC 320 to, e.g., an overlying heat sink. As described in greater detail below, the combination of vertical and lateral heat transport increases the available area, referred to herein as a heat transfer area, to transfer heat to an overlying heat sink, thereby increasing overall thermal flux and contributing to a reduction of temperature of the thermal load 350. In some cases, it is preferable to center the core 395 on the thermal load 350 to maximize thermal coupling of the core 395 to the thermal load 350.

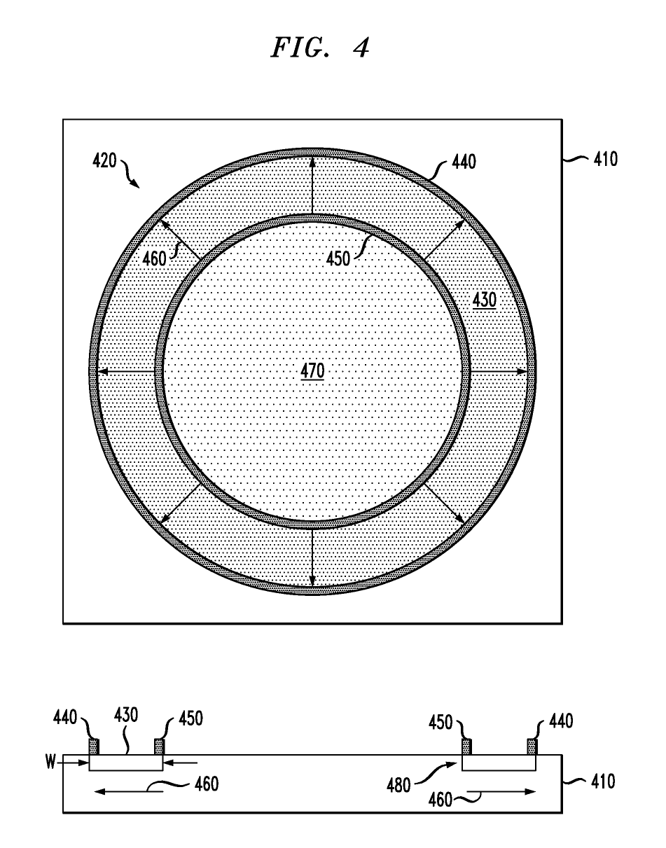

Turning to FIG. 4, a device substrate 410 is shown with a TEC 420 formed thereon. In this embodiment, the TEC 410 is structurally similar to the TEC 100c, but forms a closed loop. In this case, a single pellet 430 is electrically connected to an outer electrode 440 and an inner electrode 450. Electrical contact to the electrodes 440, 450 may be made by any conventional means, such as wire bonding. Current is passed through the pellet 430 via the electrodes 440, 450 in the direction appropriate to produce a heat flux 460 in the desired direction. The direction of the flux 460 is typically chosen to cool an enclosed region 470 of the TEC 420, though it need not be.

The pellet 430 may be, e.g., Bi₂Te₃ doped for n or p semiconducting characteristics. A recess 480 may be formed in the device substrate 410 and the pellet 430 formed or placed therein. In some cases, the pellet 430 may be preformed and placed into the recess 480. In other cases, the pellet may be formed in the recess, e.g., by physical vapor deposition (PVD) and patterning of Bi₂Te₃ and metal layers. Such techniques have been adapted to thin-film Cartesian TECs. The TEC 420 may also include insulating layers, not shown, between the pellet 430 and the device substrate 410. If used, these layers may also be formed by PVD or chemical vapor deposition (CVD) and patterned. In cases in which the electrical conductivity of the device substrate 410 is sufficiently low, insulating layers may be unnecessary. The electrodes 440, 450 may also include any desired barrier layers.

In the case that the device substrate 410 is a semiconductor wafer, such as silicon, e.g., the pellet 430 may be formed by implanting a dopant into the device substrate 410. In a non-limiting example, phosphorous or arsenic may be implanted in a region of the device substrate 410 to form a pellet of a desired shape. Conventional integrated circuit manufacturing methods may be used to form appropriate barrier and metal layers to form electrodes to provide electrical connection to the pellet. Well-known relationships between the dopant concentration and conductivity may be used to determine doping levels to result in desired operating characteristics. However, limitation on the depth of dopant implantation and diffusion may limit the effective depth of the cooling effect in the device substrate 410.

The size of the TEC 420 may influence the choice between a single-pellet design and a complementary-pellet design. The resistance through a single pellet will generally decrease as the circumference of the TEC 420 increases, for fixed pellet width W and thickness. A 25 μm gold wire-bond wire is typically rated to carry about 1.25 A. When the current requirement of the TEC 420 exceeds this value, in some cases a complementary-pellet design such as the TEC 100a may provide a simpler system design than would a single pellet design.

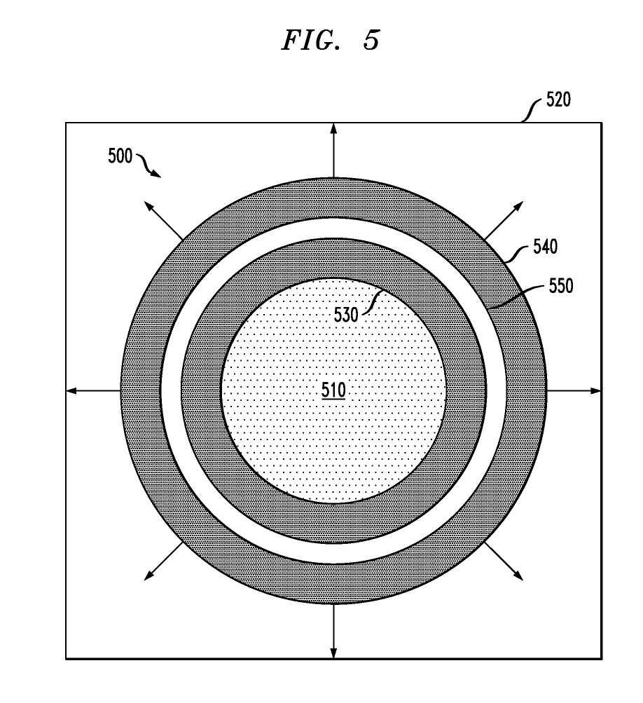

Turning now to FIG. 5, a cascaded TEC 500 is illustrated cooling an enclosed region 510 of a device substrate 520. The TEC 500 may include two or more TECs, such as, e.g., an inner TEC 530 and an outer TEC 540. The TECs 530, 540 may be electrically isolated by, e.g., an electrically insulating spacer 550 with low thermal resistance as described previously. Again, the TEC 500 may be preformed and placed in a recess in the device substrate 520. In another embodiment, not shown, a first TEC may be placed in thermal communication with a second TEC. The design and location of the TECs may be selected to provide a desired thermal flux in the vicinity of a heat dissipating load.

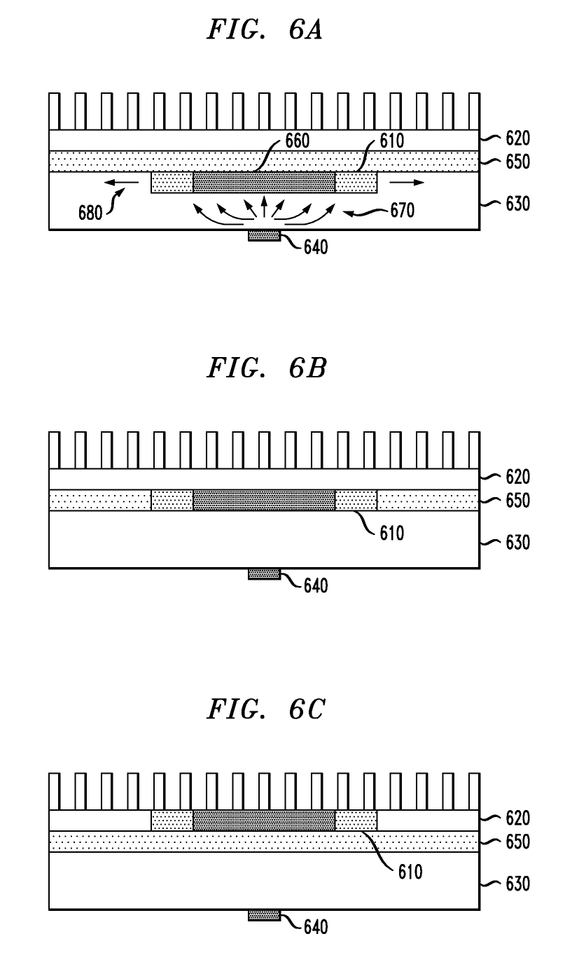

FIGS. 6A-6C illustrate various configurations of a TEC 610 and a heat sink 620 on a device substrate 630. In these embodiments, the TEC 610 is located to cool a thermal load 640 on the device substrate 630. A thermally conductive layer 650 such as, e.g., thermal grease is optionally placed between the device substrate 630 and the heat sink 620 to increase the thermal coupling between the heat sink 620 and the device substrate 630.

In FIG. 6A, the TEC 610 is placed in a recess formed in the device substrate 630. A thermally conductive core 660 of the TEC 610 conducts a portion of thermal flux 670 generated by the thermal load 640 vertically to the heat sink 620. The TEC 610 also transfers a portion 680 of the thermal flux 670 in a direction parallel to the surface of the device substrate 630. An effect of the combination of vertical and lateral heat transport is to increase the heat transfer area available to dissipate the thermal flux 670 from the thermal load 640. In one aspect, the heat transfer area increases about linearly with the increase of heat transfer area resulting from the lateral heat transport by the TEC 610. The power dissipation of the TEC 610 may add to the thermal flux 680, so in practice the extra thermal load attributable to the TEC 610 should be considered in the thermal budget of the substrate 630. However, when the thermal environment of the substrate 630 is properly accounted for, the increase of heat transfer area is thought to more than compensate for the added power dissipation, resulting in a net decrease in the temperature of the thermal load 640.

In FIG. 6B, the TEC 610 is placed in the thermally conductive layer 650. While the TEC 610 is placed farther from the load 640, thereby increasing the thermal resistance therebetween, this embodiment does not require formation of a recess in the device substrate 630. Thus, the manufacturing of this embodiment may be simpler than that shown in FIG. 6B.

In FIG. 6C, the TEC 610 is placed in a recess formed in the heat sink 620. This embodiment places the TEC 610 still farther from the load 640, but may simplify placement of the TEC 610 relative thereto. In this embodiment, the TEC 610 and the heat sink 620 may be manufactured as an integrated unit and mated to the device substrate 630 at a later stage of manufacture.

The thickness of the TEC 610 may be chosen to be appropriate to the placement of the TEC 610. For example, the TEC 610 may be thicker when placed in the heat sink 620 than in the thermally conductive layer 650. When placed in the substrate 630, the thickness may be chosen to leave a minimum remaining thickness of the substrate 630 after a recess is formed therein. The TEC 610 may be formed by a variety of techniques, including thin film fabrication and assembly of discrete pellets and electrodes. However, the scope of the description is not limited to any particular range of thickness or assembly method.

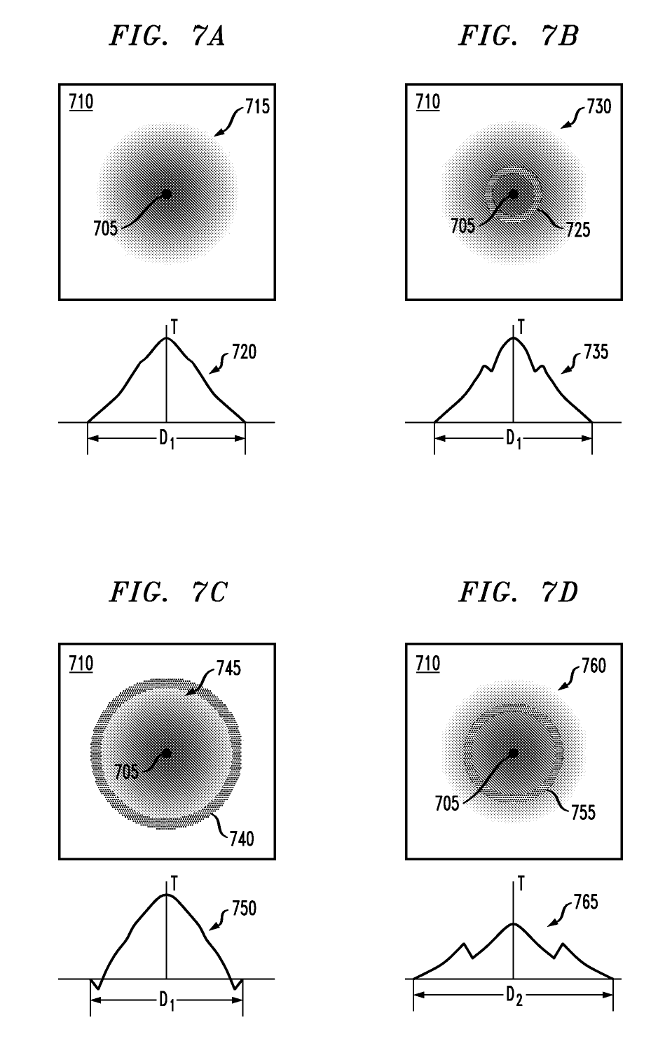

Turning to FIGS. 7A-7D, illustrated are temperature profiles associated with a thermal load 705 on a device substrate 710. FIGS. 7B-7D include TECs of various diameters. These figures represent a one-dimensional, circular-symmetric case for illustration, but in general temperature profiles of physical devices and substrates are expected to be more complex.

FIG. 7A illustrates the thermal load 705 on the device substrate 710, and an associated heat transfer area 715 in the absence of active heat transport. In the following discussion of FIGS. 7B-7D, FIG. 7A represents a “default” case. A default temperature profile 720 illustrates general characteristics of the temperature of the thermal load 705 and the heat transfer area 715. A peak temperature is associated with the location of the thermal load 705, and the temperature decreases monotonically to a background temperature of the device substrate 710 with increasing distance from the thermal load 705. A diameter D₁ describes the lateral extent of the area 715 on the device substrate 710.

FIG. 7B illustrates the thermal load 705 and a TEC 725 with a relatively small diameter. A heat transfer area 730 is associated with the thermal load 705 and the TEC 725. A temperature profile 735 describes the temperature characteristics of the area 730. The profile 735 is thought to be qualitatively similar to the case represented by the default profile 720. In particular, the profile 735 is described by a similar peak temperature of the thermal load 705 and by a diameter D₁ about equal to the diameter D₁ in FIG. 7A. It is believed that in this case, because the TEC 725 is embedded within the zone 730, it has little effect on the resulting peak temperature and diameter of the zone 730. However, the profile 735 is distinguished from the default profile 720 by the presence of a nonmonotonic feature associated with the temperature gradient across the TEC 725.

FIG. 7C illustrates the thermal load 705 and a TEC 740 with a relatively large diameter. The TEC 740 is outside of a heat transfer area 745 that has a temperature profile 750 that is qualitatively similar to the default profile 720. Again, a peak temperature and diameter D₁ of the temperature profile 750 are about the same as the default case. In this case, a nonmonotonic feature of the profile 750 occurs at the larger diameter of the TEC 740.

FIG. 7D illustrates the thermal load 705 and a TEC 755 with a diameter between that of the TEC 725 and the TEC 740. The TEC 755 is within the diameter D₁ associated with the zone 715. In this case, the TEC 755 is thought to transfer a portion of the heat generated by the thermal load 705 beyond the diameter D₁. A resulting heat transfer area 760 has a larger diameter than the area 715, providing a greater area from which to transfer heat to a heat sink. The greater area is thought to reduce the thermal resistance between the thermal load 705 and the heat sink, thereby reducing the temperature of the thermal load 705. A temperature profile 765 associated with the area 760 has a lower peak temperature relative to the profiles 720, 735, 750, as well as the larger diameter D₂ of the heat transfer area 760.

While a circular TEC was used to illustrate the principles involved, in general the shape of a TEC used to cool a load may be arbitrary. The shape may be chosen to accommodate the local physical and thermal environment of a thermal load being cooled or heated. The distance between the TEC and the thermal load, and the heat transporting capacity of the TEC will generally need to be determined taking these variables into account, as well as the power dissipation of the thermal load. In some cases, multiple TECs may be used to cool the load when needed to produce the desired cooling or heating.

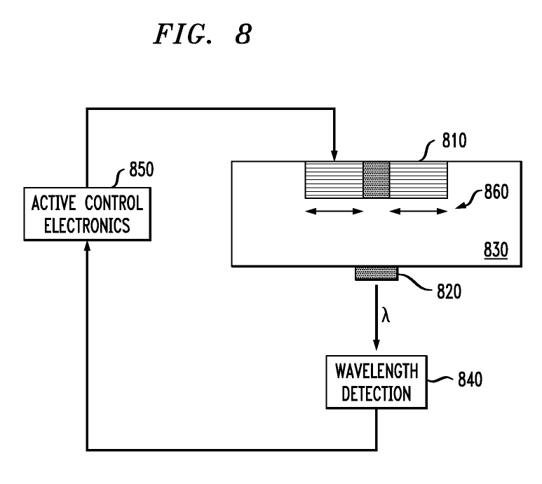

Turning to FIG. 8, an embodiment is illustrated in which a TEC 810 formed as described herein is used to transport heat to and from an electronic device 820 on a device substrate 830 to actively maintain a desired operating temperature. In a nonlimiting example, the electronic device 820 is a laser outputting light with a wavelength λ. A detector 840 converts the wavelength to a signal to active control electronics 850. The control electronics 850 in turn provide an electrical signal to the TEC 810. While the TEC 810 is illustrated embedded in a recess in the device substrate 830, embodiments are not so limited. The control electronics 850 actively control the TEC 810 to transport heat to or from the electronic device 820 as indicated by the bidirectional heat flux vectors 860. The active control acts to maintain the temperature of the electronic device 820 in a range that results in control of A within a desired range.

Although the present embodiments has been described in detail, those skilled in the art should understand that they could make various changes, substitutions and alterations herein without departing from the spirit and scope of the invention in its broadest form.

What is claimed is:

1. An apparatus, comprising:
a thermoelectric cooler adjacent to a surface of a device substrate and including a first set of one or more metal electrodes, a second set of one or more metal electrodes, and one or more semiconductor members, each member comprising a material different from said device substrate and physically joining a corresponding one electrode of said first set to a corresponding one electrode of said second set; and
wherein said electrodes and at least one member are configured to transport heat to or from a thermal load in a direction parallel to the surface of said device substrate.

2. The apparatus of claim 1, wherein said one or more semiconductor members includes one or more pairs of complementary-doped semiconductor members, the two members of each pair being connected by an electrode from said first set or said second set.

3. The apparatus of claim 1, wherein said first set includes a plurality of said metal electrodes and said second set includes a plurality of said metal electrodes, and said sets of electrodes and said members form an electrical conduction path along which said members alternate with said electrodes and said electrodes of said first set alternate with said members of said second set.

4. The apparatus of claim 3, wherein said members alternate in dopant type along-said path.

5. The apparatus of claim 1, wherein at least a portion of said thermoelectric cooler is embedded in said device substrate.

6. The apparatus of claim 1, wherein at least one of said members forms a closed loop.

7. The apparatus of claim 6, wherein said metal electrodes of said first set are located in a central region, and said electrodes of said second set are located in an annular region surrounding said central region.

8. The apparatus of claim 1, wherein at least one member comprises a doped region of said device substrate.

9. The apparatus of claim 1, wherein said members comprise bismuth telluride.

10. The apparatus of claim 1, further comprising an electronic device being on said device substrate and adjacent to one of the sets of electrodes of said thermoelectric cooler and being configured to dissipate power.

11. The apparatus of claim 1, wherein said thermoelectric cooler includes a first thermoelectric cooler and a second thermoelectric cooler cascaded with said first thermoelectric cooler.

12. The apparatus of claim 1, further comprising a heat sink adjacent to a surface of said thermoelectric cooler opposite to a surface of said thermoelectric cooler that is adjacent to the surface of the device substrate.

13. The apparatus of claim 12, wherein said thermoelectric cooler is embedded in a surface of said heat sink.

14. A method, comprising:
forming a thermoelectric cooler adjacent a surface of a device substrate, the cooler including a first set of one or more metal electrodes, a second set of one or more metal electrodes, and one or more semiconductor members comprising a material different from said device substrate, each member physically joining a corresponding one electrode of said first set to a corresponding one electrode of said second set,
configuring said electrodes and at least one member to transport heat to or from a thermal load on said device substrate in a direction parallel to the adjacent surface of said device substrate.

15. The method of claim 14, further comprising forming said thermoelectric cooler in a recessed portion of said device substrate.

16. The method of claim 14, further comprising forming said thermoelectric cooler in a recessed portion of a surface of a heat sink and locating the surface of said heat sink adjacent the surface of said device substrate.

17. The method of claim 14, wherein said thermoelectric cooler is configured to transport heat from a smaller area of said device substrate to a larger area of said device substrate.

18. The method of claim 14, wherein said thermoelectric cooler is configured to transport heat from a larger area to a smaller area.

19. The method as recited in claim 14, further comprising coupling said thermoelectric cooler to a feedback control system configured to operate said thermoelectric cooler to transport heat to and from said thermal load to maintain a desired temperature of said thermal load.

20. A method, comprising:
increasing a heat transfer area associated with an electronic device on a device substrate by operating a thermoelectric cooler adjacent said electronic device,
wherein
said thermoelectric cooler includes a first set of one or more metal electrodes, a second set of one or more metal electrodes, and one or more semiconductor members, each member physically joining a corresponding one electrode of said first set to a corresponding one electrode of said second set;
said sets of electrodes and said one or more members form an electrical conduction path within said members that is parallel to said device substrate; and
said one or more semiconductor members is formed of a material different than said device substrate and has a cross-sectional area that increases in a direction parallel to said electrical conduction path.
